(19) United States
(12) Patent Application Publication
(10) Pub. No.: US 2016/0104540 A1
(43) Pub. Date: Apr. 14, 2016

(54) NON-VOLATILE MEMORY DEVICE AND OPERATING METHOD THEREOF

(71) Applicant: SK hynix Inc., Icheon-si Gyeonggi-do (KR)

(72) Inventor: Dong Hun LEE, Suwon-si Gyeonggi-do (KR)

(21) Appl. No.: 14/639,746

(22) Filed: Mar. 5, 2015

(30) Foreign Application Priority Data
Oct. 13, 2014 (KR) 10-2014-0137818

(51) Int. Cl. G11C 16/34; G11C 16/04; G11C 16/14

(52) U.S. Cl. CPC G11C 16/3445; G11C 16/14; G11C 16/0483

(57) ABSTRACT

An operating method of a non-volatile memory device may include erasing memory cells included in a plurality of strings of a memory block, wherein the memory cells are coupled between a bit line and a common source line. The operating method of the non-volatile memory device may include performing an erase verify operation on selected memory cells having a low erase speed, among the memory cells. The operating method of the non-volatile memory device may include repeating the erasing of the memory cells and the performing of the erase verify operation until the erase verify operation passes.

### CROSS-REFERENCE TO RELATED APPLICATION

The present application claims priority to Korean patent application number 10-2014-0137818 filed on Oct. 13, 2014, in the Korean Intellectual Property Office, the entire disclosure of which is incorporated by reference herein.

### BACKGROUND

1. Technical Field

Various embodiments relate generally to a non-volatile memory device and an operating method thereof and, more particularly, to an erase operation of a three-dimensional non-volatile memory device.

2. Related Art

Non-volatile memory devices may be classified into two-dimensional (2D) non-volatile memory devices or three-dimensional (3D) non-volatile memory devices. In a 2D non-volatile memory device, strings are arranged in parallel with a direction towards a substrate. In a 3D non-volatile memory device, strings are arranged in a vertical direction towards a substrate. For example, the 3D non-volatile memory device may include a plurality of vertical channel layers arranged in a vertical direction towards the substrate. Memory layers surround the vertical channel layers. The 3D non-volatile memory device may also include a plurality of word lines stacked and separated from each other along the memory layers.

However, unlike the 2D non-volatile memory device, word lines of the 3D non-volatile memory device are stacked with different layers. Therefore, resistance may exist between the word lines, and such electric difference may lower the operation reliability of the 3D non-volatile memory device.

### BRIEF SUMMARY

An operating method of a non-volatile memory device according to an embodiment may include erasing memory cells included in a plurality of strings of a memory block. The memory cells may be coupled between a bit line and a common source line. The operating method may include performing an erase verify operation on selected memory cells having a low erase speed, among the memory cells. The operating method may include repeating the erasing of the memory cells and the performing of the erase verify operation until the erase verify operation passes.

A non-volatile memory device according to an embodiment may include a memory block configured for storing data, a circuit group configured for performing a test operation and a main erase operation on the memory block, and a storage unit configured for storing address information about a page including slow cells. The non-volatile memory device may include a control circuit configured for controlling the circuit group to erase memory cells included in the memory block during the main erase operation, perform an erase verify operation on the slow cells on the basis of the address information, and perform the main erase operation until the erase verify operation passes.

### BRIEF DESCRIPTION OF THE DRAWINGS

FIG. 1 is a diagram illustrating a representation of an example of a semiconductor device according to an embodiment.

FIG. 2 is a flowchart illustrating a representation of an example of a test operation according to an embodiment.

FIG. 3 is a view illustrating a representation of an example of a method of selecting slow cells during a test ease verify operation illustrated in FIG. 2.

FIG. 4 is a flowchart illustrating a representation of an example of an erase operation according to an embodiment.

FIG. 5 is a perspective view illustrating a representation of an example of strings having a three-dimensional structure.

FIG. 6 is diagram illustrating a representation of an example of an erase operation according to a first embodiment.

FIG. 7 is a diagram illustrating a representation of an example of an erase operation according to a second embodiment.

FIG. 8 is a perspective view illustrating a representation of an example of strings having a three-dimensional structure according to an embodiment.

FIG. 9 is a diagram illustrating a representation of an example of an erase operation according to a third embodiment.

FIG. 10 is a diagram illustrating a representation of an example of an erase operation according to a fourth embodiment.

FIG. 11 is a block diagram illustrating a representation of an example of a solid state drive including a semiconductor device according to an embodiment.

FIG. 12 is a block diagram illustrating a representation of an example of a memory system including a semiconductor device according to an embodiment.

FIG. 13 is a schematic block diagram illustrating a representation of an example of a computing system including a semiconductor device according to an embodiment.

### DETAILED DESCRIPTION

Hereinafter, various examples of embodiments will be described in detail with reference to the accompanying drawings. The figures are provided to allow those with ordinary skill in the art to understand the scope of the various embodiments. The present disclosure may, however, be embodied in different forms and should not be construed as limited to the embodiments set forth. Rather, these embodiments are provided so that this disclosure will be thorough and complete. In addition, the embodiments are provided to fully convey the scope of the application to those skilled in the art.

Various embodiments generally may relate to a non-volatile memory device capable of improving the reliability of an erase operation of a three-dimensional memory device, and an operating method thereof.

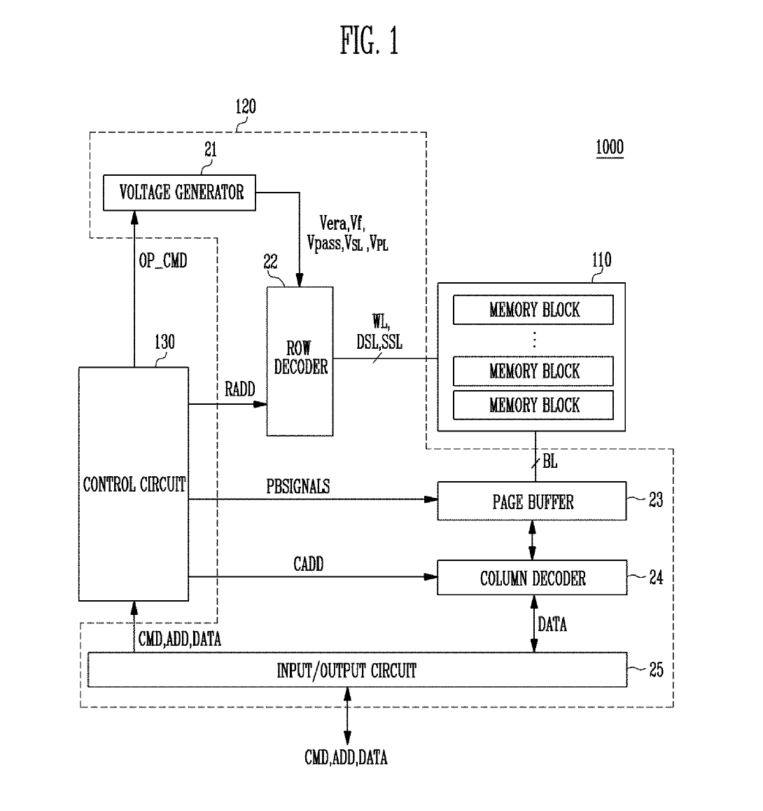

FIG. 1 is a diagram illustrating a representation of an example of a semiconductor device 1000 according to an embodiment.

Referring to FIG. 1, the semiconductor device 1000 may include a memory cell array 110 configured for storing data, and a circuit group 120 configured to perform a program operation, a read operation, or an erase operation of the memory cell array 110. The semiconductor device 1000 may include a control circuit 130 configured to control the circuit group 120.

The memory cell array 110 may include a plurality of memory blocks having substantially the same configuration as each other. Each of the memory blocks may include a plurality of strings. Each of the plurality of strings may include a plurality of memory cells storing data and have a three-dimensional structure arranged in a vertical direction or substantially a vertical direction with relation to the substrate. The memory cells may include single level cells (SLC) in which one bit of data is stored, multi level cells (MLC), triple level cells (TLC), or quadruple level cells (QLC) in which two bits of data may be stored. For example, two bits of data may be stored in each of the multi-level cells (MLC), three bits of data may be stored in each of the triple level cells (TLC), and four bits of data may be stored in each of the quadruple level cells (QLC).

The circuit group 120 may include a voltage generator 21, a row decoder 22, and a page buffer 23. The circuit group 120 may include a column decoder 24 and an input/output circuit 25.

The voltage generator 21 may generate operating voltages including various levels in response to an operation command signal OP_CMD. For example, to perform an erase operation, the voltage generator 21 may generate, for example but not limited to, an erase voltage Vera, a pass voltage Vpass, an erase verify voltage Vf, a select turn-on voltage VSL, and a pipe turn-on voltage VPL. The voltage generator 21 may generate various voltages necessary for various operations. During the erase operation, the erase voltage Vera, the pass voltage Vpass, the erase verify voltage Vf, the select turn-on voltage VSL and the pipe turn-on voltage VPL may be applied to the row decoder 22.

The row decoder 22 may select one of the memory blocks included in the memory cell array 110. The row decoder 22 may select one of the memory blocks included in the memory cell array 110 in response to a row address RADD and may transfer the operating voltages to word lines WL, drain selection lines DSL and source selection lines SSL connected to a selected memory block.

The page buffer 23 may be connected to or electrically coupled to the memory blocks through bit lines BL. The page buffer 23 may exchange data with the selected memory block during a program, read and/or erase operation, and may temporarily store the transferred data in response to page buffer control signals PBSIGNALS.

The column decoder 24 may exchange data with the page buffer 23. The column decoder 24 may exchange data with the page buffer 23 in response to a column address CADD.

The input/output circuit 25 may transfer a command signal CMD and an address ADD, transferred from an external device, to the control circuit 130. The input/output circuit 25 may transfer data DATA, transferred from an external device, to the column decoder 24, and output the data DATA transferred from the column decoder 24 to an external device, or transfer the data DATA to the control circuit 130.

The control circuit 130 may control the circuit group 120 in response to the command signal CMD and the address ADD. The control circuit 130 may control the circuit group 120 so that the circuit group 120 may determine slow cells during a test erase operation of the semiconductor device 1000 and store an address of the slows cells. The control circuit 130 may perform an erase operation subsequent to the test erase operation while performing an erase verify operation only on the slow cells on the basis of stored address information.

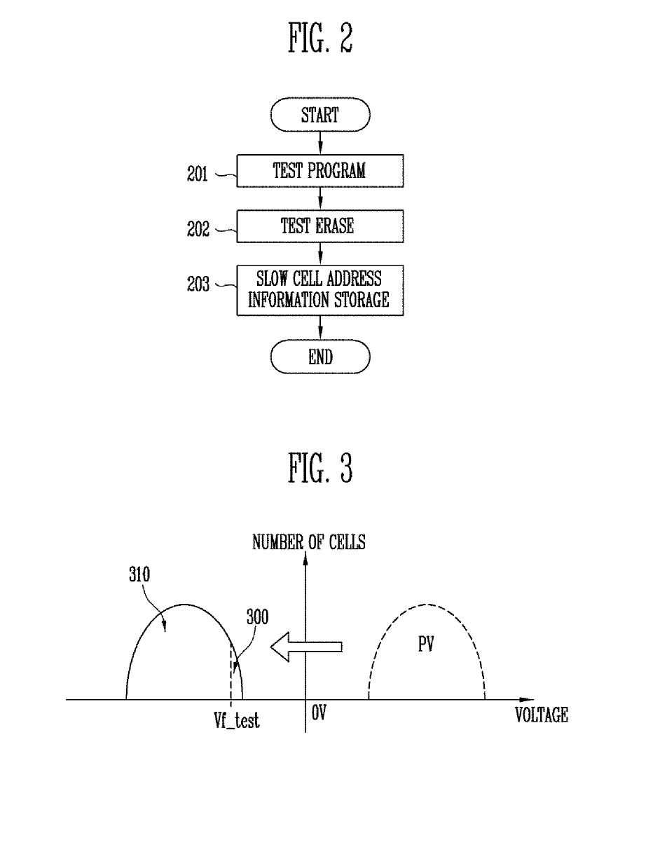

FIG. 2 is a flowchart illustrating a representation of an example of a test erase operation according to an embodiment.

Referring to FIG. 2, a test program operation may be performed (201) before a test erase operation is performed (202). For example, the test program operation may be performed by programming a selected memory block, among the memory blocks included in the memory cell array 110 (see FIG. 1), with arbitrary test data. The test program operation may be performed by, for example, an incremental step pulse program (ISPP) method, or without performing a program verify operation.

After the test program operation is completed, the test erase operation may be performed (202). The test erase operation may be performed by applying a test erase voltage to a bit line, a common source line, and a pipe line coupled to the selected memory block. For example, the test erase operation may be performed by applying the test erase voltage of a single pulse to the bit line, the common source line, and the pipe line for a predetermined period of time, or by applying a plurality of erase pulses having substantially the same level as the test erase voltage for a predetermined period of time.

After memory cells included in the selected memory block are erased, slow cells may be selected from among the erased memory cells, and an address of the selected slow cells may be stored (203). To determine the slow cells, a test erase verify operation may be performed. The test erase verify operation may be performed by using a test verify voltage. For example, the test erase verify operation may be performed by applying the test verify voltage to all word lines coupled to the selected memory block. During the test erase verify operation, memory cells having higher threshold voltages than the test verify voltage may be selected as the slow cells, and address information about a page including the selected slow cells may be stored in a storage unit of the semiconductor device 1000, illustrated in FIG. 1.

A page may refer to a group of memory cells coupled to the same word line. Therefore, in a three-dimensionally structured semiconductor device, a page may refer to a group of memory cells included in the same layer in the selected memory block. An arbitrary storage unit included in the semiconductor device 1000 may be used as the storage unit in which the address information on the page including the slow cells is stored. For example, a storage unit included in the control circuit 130, illustrated in FIG. 1, some memory cells (e.g., flag cells) included in the memory cell array 110 may be used, and a separate storage unit storing only an address of a page extracted through a test operation may be used.

When a result of the test erase verify operation on a selected page is determined as a fail, the address information about the selected page may be stored in the storage unit. The above-described test erase operation (201, 202 and 203) may be performed on each of the memory blocks. The address information about the page including the slow cells may vary according to each memory block.

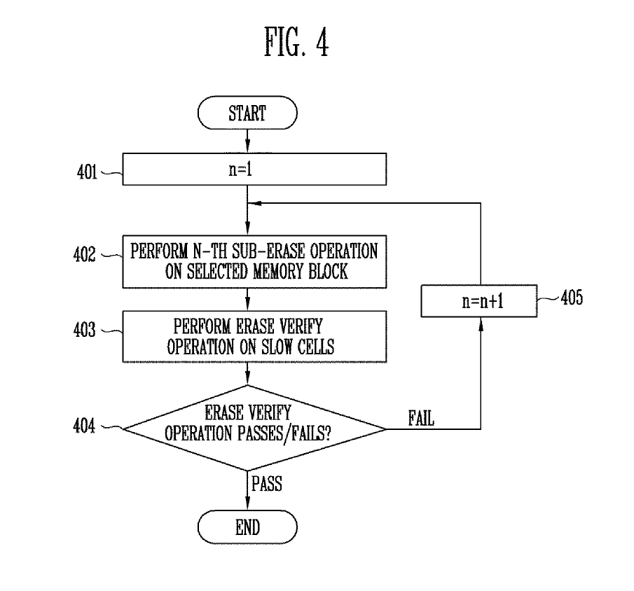

FIG. 3 is a view illustrating a representation of an example of a method of selecting slow cells during the test erase verify operation illustrated in FIG. 2.

Referring to FIG. 3, when a test erase operation is performed on memory cells PV on which a test program operation is performed, threshold voltages of the memory cells may be reduced (310). However, despite the same test erase voltage, each memory cell may be erased at a different speed due to difference in electrical characteristics thereof. Memory cells having higher threshold voltages (300) than a test verify voltage Vf_test, among threshold voltages (310) of the erased memory cells, may be erased at a slower rate than memory cells having lower threshold voltages than the test verify voltage Vf_test. The test verify voltage Vf_test may be set between 0V and an erase verify voltage. The erase verify voltage may refer to a verify voltage applied during an erase operation which may generally be performed after the test erase operation.

FIG. 4 is a flowchart illustrating a representation of an example of an erase operation according to an embodiment.

Referring to FIG. 4, an erase operation may be performed by using an incremental step pulse erase (ISPE). The erase operation may be defined as a main erase operation so as to be differentiated from the above-described test erase operation. The erase operation using the ISPE method may include a plurality of sub-erase operations and erase verify operations. The sub-erase operations may be performed on memory cells included in the selected memory block. The erase verify operations may be performed only on the pages including the slow cells. The erase operation is described below.

When the erase operation starts, an n-th sub-erase operation of the selected memory block may be performed (402). For example, the n-th sub-erase operation may be performed by applying an erase voltage to bit lines and common source lines, applying a select turn-on voltage to drain and source selection lines, and coupling word lines to a ground terminal. Here, ‘n’ may refer to the number of sub-erase operations, where n is a positive integer, and be set to an initial value of ‘1’ (401). The n-th sub-erase operation first performed may be a first sub-erase operation.

An erase verify operation may be performed after the first sub-erase operation is performed (403). The erase verify operation may be performed only on the page including the slow cells. In other words, since threshold voltages of memory cells having a faster erase operation speed than the slow cells are lower than those of the slow cells for the same erase operation, an erase verify operation on the other memory cells except for the slow cells may be unnecessary.

In addition, in a three-dimensionally structured semiconductor device, even when it is assumed that memory cells formed in different layers have the same electrical characteristics, word lines included in different pages may be formed in different layers in terms of manufacturing processes. Therefore, an electrical difference, such as resistance, may occur. In other words, word lines formed in the same page, i.e., in the same layer may have similar electrical characteristics, whereas word lines formed in different layers may have different electrical characteristics. This electrical difference between the word lines may cause slow cells.

During the erase verify operation (403), a page including the slow cells may be selected based on address information stored during the test operation. After the erase verify operation is selectively performed on pages including the slow cells (403), pass or fail of the erase verify operation may be determined according to a result of the erase verify operation (404). For example, when threshold voltages of the slow cells are lower than the erase verify voltage, the erase verify operation may be determined as a pass, and otherwise, the erase verify operation may be determined as fail.

When the erase verify operation on the slow cells included in the selected page passes, threshold voltages of other memory cells included in the selected memory block may be determined to have a lower voltage level than the erase verify voltage. Therefore, the erase operation of the selected memory block may be terminated.

When the erase verify operation of the slow cells included in the selected page fails, a second sub-erase operation (402) may be performed according to ‘n=n+1’ (405). The second sub-erase operation may be performed by using a higher erase voltage than the first sub-erase operation.

As described above, the sub-erase operation may be performed on the selected memory block. The erase verify operation may be performed only on the page including the slow cells, so that power consumption for the erase operation may be reduced. In addition, since the erase verify operation is performed on the basis of the page including the slow cells, operating conditions similar to a read operation may be satisfied. Therefore, the reliability of a read operation as well as the erase operation may be improved. In addition, stress applied to memory cells of pages not including the slow cells may be reduced during the erase operation. Therefore, performance degradation of the semiconductor device may be suppressed, and reliability may be improved.

Since a three-dimensional semiconductor device may include strings with different structures, a method of performing an erase operation may differ according to the structure of a string. Respective string structures and erase operations thereof are described below.

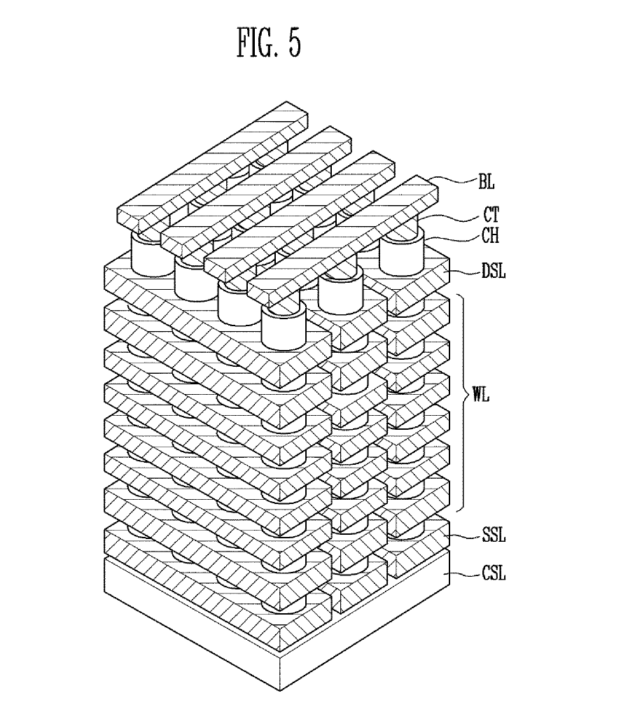

FIG. 5 is a perspective view illustrating a representation of an example of three-dimensionally structured strings according to an embodiment.

Referring to FIG. 5, three-dimensionally structured strings according to an embodiment may be arranged in a vertical direction between the bit lines BL and a common source line CSL. This structure may be referred to as a bit cost scalable (BiCS) structure. For example, when the common source line CSL is formed in a horizontal direction with respect to the substrate, the strings having a BiCS structure may be formed in a vertical direction with respect to the common source line CSL. The strings may include the source selection lines SSL, the word lines WL, the drain selection lines DSL, and the vertical channel layers CH. The source selection lines SSL, the word lines WL and the drain selection lines DSL may be arranged in a first direction. The source selection lines SSL, the word lines WL and the drain selection lines DSL may be stacked and separated from each other. The vertical channel layers CH may vertically pass through the source lines SSL, the word lines WL, and the drain selection lines DSL and contact the common source line CSL. The bit lines BL may contact top portions of the vertical channel layers CH protruding over the drain selection lines DSL and be arranged in a second direction orthogonal or substantially orthogonal to the first direction. Contact plugs CT may be further formed between the bit lines BL and the vertical channel layers CH.

An erase operation of the semiconductor device including the strings having the above-described BiCS structure is described below.

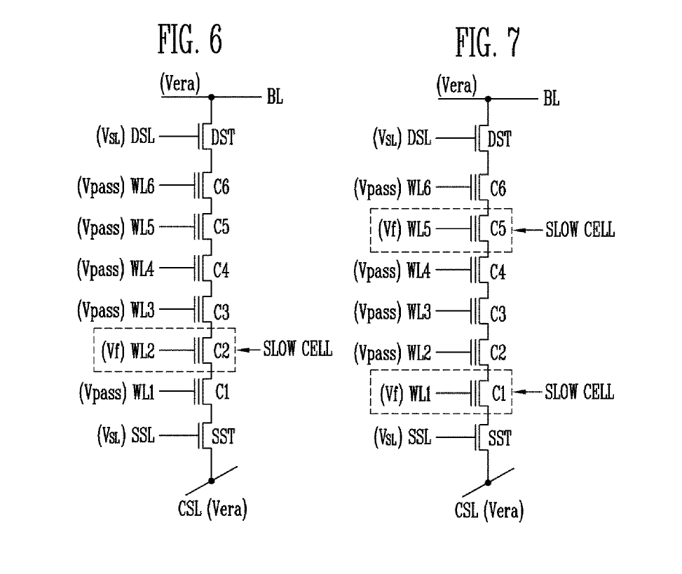

FIG. 6 is a diagram illustrating a representation of an example of an erase operation according to a first embodiment.

FIG. 6 is a circuit diagram illustrating a representation of an example of one of the strings illustrated in FIG. 5. The string may include a source selection transistor SST, first to sixth memory cells C1 to C6, and a drain selection transistor DST. The source selection transistor SST, first to sixth memory cells C1 to C6, and a drain selection transistor DST may be coupled in series between the common source line CSL and the bit line BL. In FIG. 6 one source selection transistor SST, one drain selection transistor DST, and six memory cells C1 to C6 are illustrated for convenience of explanation. However, more source selection transistors, more drain selection transistors and more memory cells may be included, depending on a semiconductor device.

After the sub-erase operation (402 in FIG. 4) is performed on the selected memory block, the erase verify operation (403 in FIG. 4) may be performed on the slow cells, among the memory cells included in the selected memory block. A detailed description of a method of selecting slow cells, from among memory cells, and selecting the slow cells during an erase verify operation is omitted since this method is described above with reference to FIG. 4. Voltages applied to respective lines when the second memory cell C2 is selected as a slow cell are described with reference to FIG. 6. When the second memory cell C2 is selected as the slow cell, the erase verify voltage Vf may be applied to a second word line WL2 coupled to the second memory cell C2, and the pass voltage Vpass may be applied to first and third to sixth word lines WL1 and WL3 to WL6.

In a three-dimensionally structured semiconductor device, since word lines formed in the same layer have similar electrical characteristics, cells coupled to the word lines formed in the same layer may have similar electrical characteristics. For example, when the second memory cell C2 included in one of the strings is a slow cell, the second memory cells C2 included in other strings may be likely to be slow cells having a slower erase speed than the first and third to sixth memory cells C1 and C3 to C6. Therefore, during the erase verify operation, the threshold voltages of the second memory cells C2 may be verified at the same time or substantially the same time by applying the erase verify voltage Vf to all the second word lines WL2 coupled to the second memory cells C2, among the word lines coupled to the selected memory block.

While the erase verify operation is performed, the erase voltage Vera may be applied to the bit lines BL and the common source line CSL, and the turn-on voltage VSL may be applied to the drain selection line DSL and the source selection line SSL. For example, the turn-on voltage VSL may be set to be greater than 0V, the pass voltage Vpass may be set to be greater than the turn-on voltage VSL, and the erase voltage Vera may be set to be greater than the pass voltage Vpass.

When the erase verify operation of the second memory cells C2 included in the selected memory block passes, the erase operation of the selected memory block may be terminated. When the erase verify operation fails due to cells whose threshold voltages are not lower than the erase verify voltage, among the second memory cells C2 included in the selected memory block, the sub-erase operation of the selected memory block and the erase verify operation of the second memory cells C2 may be repeated until the erase verify operation of the second memory cells C2 passes. Since the first and third to sixth memory cells C1 and C3 to C6 are erased at a faster rate than the second memory cells C2, the erase operation of the selected memory block may be terminated if the erase verify operation of the second memory cells C2 passes. In other words, while the erase operation of the selected memory block is performed, the erase verify operation on the first and third to sixth memory cells C1 and C3 to C6 may be omitted.

FIG. 7 is a diagram illustrating a representation of an example of an erase operation according to a second embodiment.

FIG. 7 is a circuit diagram illustrating the same string illustrated in FIG. 6. Voltages applied to respective lines when the first memory cell C1 and the fifth memory cell C5 are selected as slow cells are described with reference to FIG. 7. However, when the first and fifth memory cells C1 and C5 are selected as slow cells, the erase verify voltage Vf may be applied to the first and fifth word lines WL1 and WL5 coupled to the first and fifth memory cells C1 and C5, and the pass voltage Vpass may be applied to the second to fourth word lines WL2 to WL4 and the sixth word line WL6.

In a three-dimensionally structured semiconductor device, since word lines formed in the same layer have similar electrical characteristics, cells coupled to the word lines formed in the same layer may have similar electrical characteristics. For example, when the first and fifth memory cells C1 and C5 included in one of the strings are slow cells, the first and fifth memory cells C1 and C5 included in other strings may be likely to be slow cells which have a slower erase speed than the second to fourth memory cells C2 to C4 and the sixth memory cells C6.

Therefore, during the erase verify operation, the threshold voltages of the first and fifth memory cells C1 and C5 may be verified at the same time or substantially the same time by applying the erase verify voltage to the first and fifth word lines WL1 and WL5 coupled to the first and fifth memory cells C1 and C5, among the word lines coupled to the selected memory block. While the erase verify operation is performed, the erase voltage Vera may be applied to the bit lines BL and the common source line CSL, and the turn-on voltage VSL may be applied to the drain selection line DSL and the source selection line SSL.

When the erase verify operation of the first and fifth memory cells C1 and C5 included in the selected memory block passes, the erase operation of the selected memory block may be terminated. When the erase verify operation fails due to cells whose threshold voltages are not lower than the erase verify voltage, among the first and fifth memory cells C1 and C5 included in the selected memory block, the sub-erase operation of the selected memory block and the erase verify operation of the first and fifth memory cells C1 and C5 may be repeated until the erase verify operation of the first and fifth memory cells C1 and C5 passes. Since the second to fourth memory cells C2 to C4 and the sixth memory cells C6 are erased at a faster rate than the first and fifth memory cells C1 and C5, the erase operation of the selected memory block may be terminated if the erase verify operation on the first and fifth memory cells C1 and C5 passes. In other words, while the erase operation of the selected memory block is performed, the erase verify operation of the second to fourth memory cells C2 to C4 and the sixth memory cells C6 may be skipped.

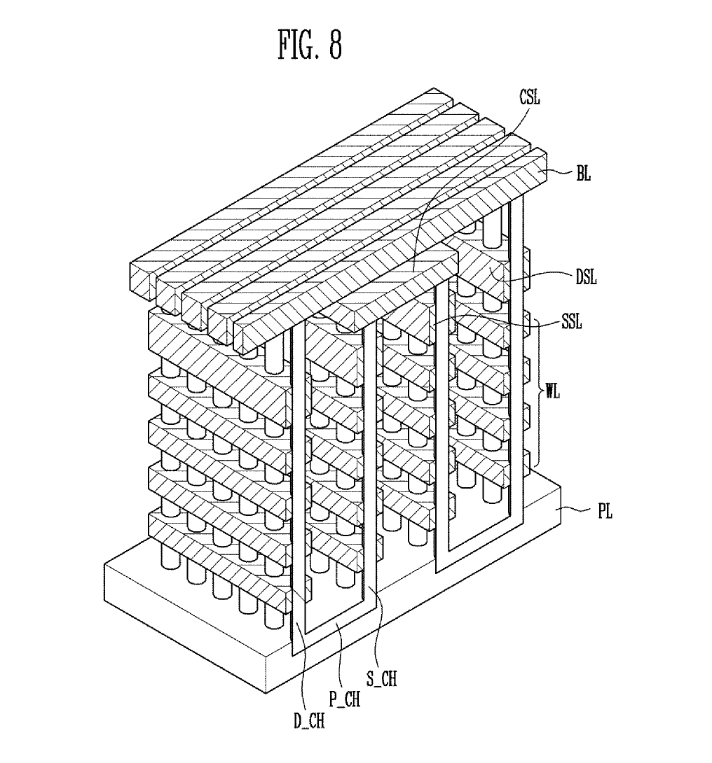

FIG. 8 is a perspective view illustrating a representation of an example of three-dimensionally structured strings according to an embodiment.

Referring to FIG. 8, strings having a three-dimensional structure according to an embodiment may include first sub-strings and second sub-strings coupled to each other in a pipe line PL. The first sub-strings may be arranged in a vertical direction between the bit lines BL and the pipe line PL. The second sub-strings may be arranged in a vertical direction between the common source line CSL and the pipe line PL. This structure may be referred to as a Pipe-shaped Bit Cost Scalable (P-BiCS) structure. For example, when the pipe line PL is formed in a horizontal direction with respect to the substrate, the strings having the P-BiCS structure may include first sub-strings and second sub-strings. The first sub-strings may be formed in a vertical direction with respect to the pipe line PL and arranged between the bit lines BL. The second sub-strings may be formed in a vertical direction with respect to the pipe line PL and arranged between the common source lines CSL.

The first sub-strings may include the word lines WL, the drain selection lines DSL, and first vertical channel layers D_CH. The word lines WL and the drain selection lines DSL may be arranged in a first direction and stacked and separated from each other. The first vertical channel layers D_CH may vertically pass through the word lines WL and the drain selection lines DSL. The second sub-strings may include the word lines WL, the source selection lines SSL, and second vertical channel layers S_CH. The word lines WL and the source selection lines SSL may be arranged in the first direction and stacked and separated from each other. The second vertical channel layers S_CH may vertically pass through the word lines WL and source selection lines SSL. The first vertical channel layers D_CH and the second vertical channel layers S_CH may be coupled to each other by pipe channel layers P_CH in the pipe line PL. The bit lines BL may contact top portions of the first vertical channel layers D_CH protruding over the drain selection lines DSL and arranged in a second direction orthogonal or substantially orthogonal to the first direction.

An erase operation of the semiconductor device having the strings having the above-described P-BiCS structure is described below.

FIG. 9 is a diagram illustrating a representation of an example of an erase operation according to a third embodiment.

FIG. 9 is a circuit diagram illustrating a representation of an example of one of the strings illustrated in FIG. 8. The string may include the source selection transistor SST, the first to fourth memory cells C1 to C4, the fifth to eighth memory cells C5 to C8, and the drain selection transistor DST. The source selection transistor SST and the first to fourth memory cells C1 to C4 may be coupled in series between the common source line CSL and the pipe transistor PT. The fifth to eighth memory cells C5 to C8 and the drain selection transistor DST may be coupled in series between the pipe transistor PT and the bit line BL. Referring to FIG. 9, one source selection transistor SST, one drain selection transistor DST, and eight memory cells C1 to C8 are illustrated for convenience of explanation. However, more source selection transistors, more drain selection transistors and more memory cells may be included depending on a semiconductor device or an embodiment.

After the sub-erase operation (420 in FIG. 4) is performed, the erase verify operation (403 in FIG. 4) may be performed on the slow cells, among the memory cells included in the selected memory block. A detailed description of a method of selecting slow cells, from among memory cells, and selecting the slow cells during an erase verify operation is omitted since this method is described above with reference to FIG. 4. Voltages applied to respective lines when the first and eighth memory cells C1 and C8 formed in the same layer are selected as slow cells may be described with reference to FIG. 9. When the first and eighth memory cells C1 and C8 are selected as the slow cells, the erase verify voltage Vf may be applied to the first and eighth word lines WL1 and WL8 coupled to the first and eighth memory cells C1 and C8, and the pass voltage Vpass may be applied to the second to seventh word lines WL2 to WL7.

In a three-dimensionally structured semiconductor device, since word lines formed in the same layer have similar electrical characteristics, cells coupled to the word lines formed in the same layer may have similar electrical characteristics. For example, when the first and eighth memory cells C1 and C8 included in one of the strings are slow cells, the first and eighth memory cells C1 and C8 included in other strings may be likely to be slow cells having a slower erase speed than the second to seventh memory cells C2 to C7. Therefore, during the erase verify operation, among the word lines coupled to the selected memory block, the threshold voltages of the first and eighth memory cells C1 and C8 may be verified at the same time or substantially the same time by applying the erase verify voltage Vf to all the first and eighth word lines WL1 and WL8 coupled to the first and eighth memory cells C1 and C8.

While the erase verify operation is performed, the erase voltage Vera may be applied to the bit lines BL and the common source line CSL, the turn-on voltage VSL may be applied to the drain selection line DSL and the source selection line SSL, and the pipe voltage VPL may be applied to the pipe line PL. For example, the turn-on voltage VSL may be set to be greater than 0V, the pass voltage Vpass may be set to be greater than the turn-on voltage VSL, the pipe voltage VPL may be set to be higher than the pass voltage Vpass, and the erase voltage Vera may be set to be greater than the pipe voltage VPL.

The erase operation on the selected memory block may be terminated when the erase verify operation on the first and eighth memory cells C1 and C8 included in the selected memory block passes. When the erase verify operation fails due to memory cells whose threshold voltages are not lower than the erase verify voltage, among the first and eighth memory cells C1 and C8 included in the selected memory block, the sub-erase operation of the selected memory block and the erase verify operation of the first and eighth memory cells C1 and C8 may be repeated until the erase verify operation of the first and eighth memory cells C1 and C8 passes. Since the second to seventh memory cells C2 to C7 are erased at a faster rate than the first and eighth memory cells C1 and C8, the erase operation of the selected memory block may be terminated if the erase verify operation of the first and eighth memory cells C1 and C8 passes. In other words, the erase verify operation of the second to seventh memory cells C2 to C7 may be skipped while the erase operation is performed on the selected memory block.

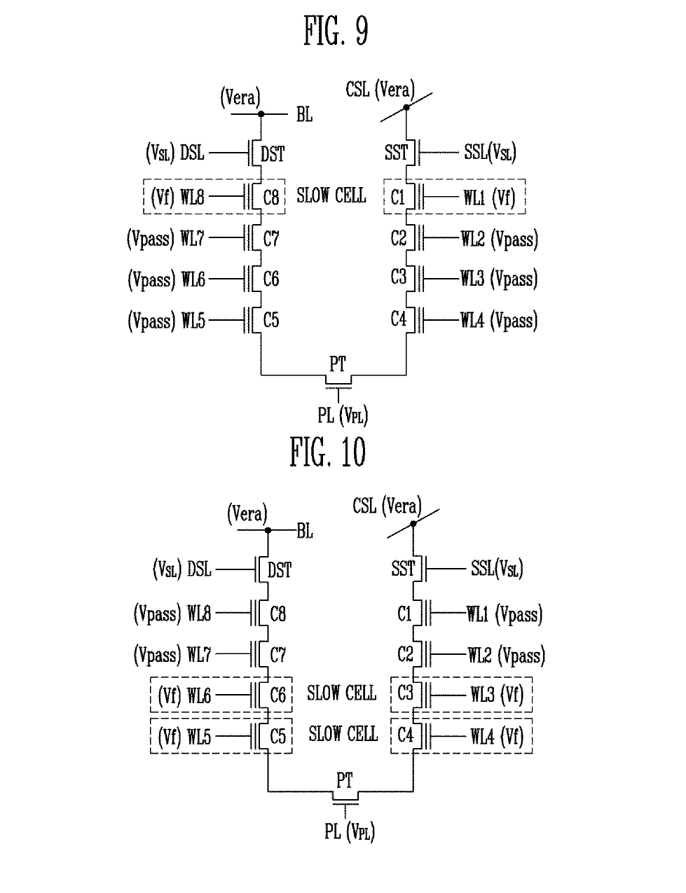

FIG. 10 is a diagram illustrating a representation of an example of an erase operation according to a fourth embodiment.

FIG. 10 is a circuit diagram illustrating a representation of an example of the same string as illustrated in FIG. 9. Voltages applied to respective lines when the third and sixth memory cells C3 and C6 and the fourth and fifth memory cells C4 and C5 formed in different layers are selected as slow cells are described with reference to FIG. 10. When the third to sixth memory cells C3 to C6 are selected as slow cells, the erase verify voltage Vf may be applied to the third to sixth word lines WL3 to WL6 coupled to the third to sixth memory cells C3 to C6, and the pass voltage Vpass may be applied to the first, second, seventh and eighth word lines WL1, WL2, WL7 and WL8.

In a three-dimensionally structured semiconductor device, since word lines formed in the same layer have similar electrical characteristics, cells coupled to the word lines formed in the same layer may have similar electrical characteristics. For example, when the third to sixth memory cells C3 to C6 included in one of the strings are slow cells, the third to sixth memory cells C3 to C6 included in other strings may be slow cells which have a slower erase speed than the first, second, seventh and eighth memory cells C1, C2, C7 and C8. Therefore, during the erase verify operation, the threshold voltages of the third to sixth memory cells C3 to C6 may be verified at the same time or substantially the same time by applying the erase verify voltage to the third to sixth word lines WL3 to WL6 coupled to the third to sixth memory cells C3 to C6, among the word lines coupled to the selected memory block. While the erase verify operation is performed, the erase voltage Vera may be applied to the bit lines BL and the common source line CSL, the pipe voltage VPL may be applied to the pipe line PL, and the turn-on voltage VSL may be applied to the drain selection line DSL and the source selection line SSL.

When the erase verify operation on the third to sixth memory cells C3 to C6 included in the selected memory block passes, the erase operation of the selected memory block may be terminated. When the erase verify operation of the third to sixth memory cells C3 to C6 fails due to memory cells whose threshold voltages are not lower than the erase verify voltage, among the third to sixth memory cells C3 to C6 included in the selected memory block, the sub-erase operation of the selected memory block and the erase verify operation of the third to sixth memory cells C3 to C6 may be repeated until the erase verify operation on the third to sixth memory cells C3 to C6 passes.

Since the first, second, seventh and eight memory cells C1, C2, C7 and C8 are erased at a faster rate than the third to sixth memory cells C3 to C6, the erase operation on the selected memory block may be terminated if the erase verify operation on the third to sixth memory cells C3 to C6 passes. In other words, the erase verify operation on the first, second, seventh and eighth memory cells C1, C2, C7 and C8 may be terminated while the erase operation is performed on the selected memory block.

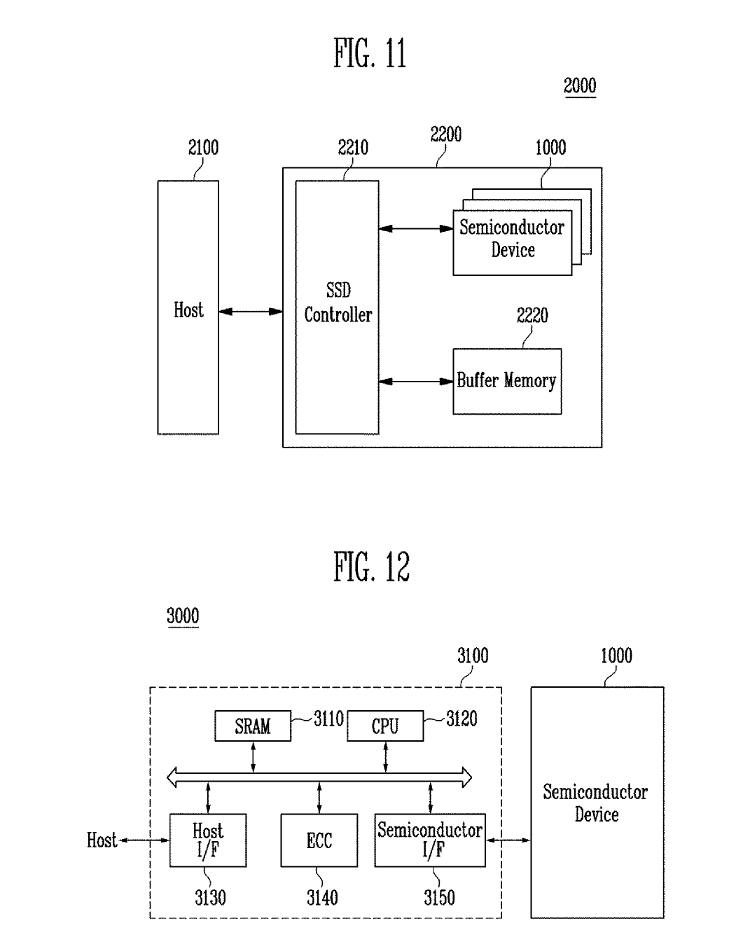

FIG. 11 is a block diagram illustrating a representation of an example of a solid state drive including a semiconductor device according to an embodiment.

Referring to FIG. 11, a drive device 2000 may include a host 2100 and an SSD 2200. The SSD 2200 may include an SSD controller 2210, a buffer memory 2220 and a semiconductor device 1000.

The SSD controller 2210 may provide a physical connection between the host 2100 and the SSD 2200. In other words, the SSD controller 2210 may perform interfacing with the SSD 2200 in response to a bus format of the host 2100. The SSD controller 2210 may decode a command provided from the host 2100. According to a decoding result, the SSD controller 2210 may access the semiconductor device 1000. As the bus format of the host 2100, Universal Serial Bus (USB), Small Computer System Interface (SCSI), Peripheral Component Interconnect Express (PCI-E), Advanced Technology Attachment (ATA), Parallel ATA (PATA), Serial ATA (SATA), and Serial Attached SCSI (SAS) may be included.

The buffer memory 2220 may temporarily store program data provided from the host 2100 or data read from the semiconductor device 1000. When a read request is made by the host 2100, if data in the semiconductor device 1000 is cached, the buffer memory 2220 may support a cache function to directly provide the cached data to the host 2100. In general, data transfer speed by the bus format (for example, SATA or SAS) of the host 2100 may be higher than the transfer speed of a memory channel of the SSD 2200. In other words, when an interface speed of the host 2100 is higher than the transfer speed of the memory channel of the SSD 2200, performance degradation caused by the speed difference may be minimized by providing a buffer memory 2220 having a large capacity. The buffer memory 2220 may be provided as Synchronous DRAM in order to provide sufficient buffering in the SSD 2200.

The semiconductor device 1000 may be provided as a storage medium of the SSD 2200. For example, the semiconductor device 1000 may be provided as a nonvolatile memory device having large storage capacity as described above in detail with reference to FIG. 1. The semiconductor device 1000 may be a NAND-type flash memory.

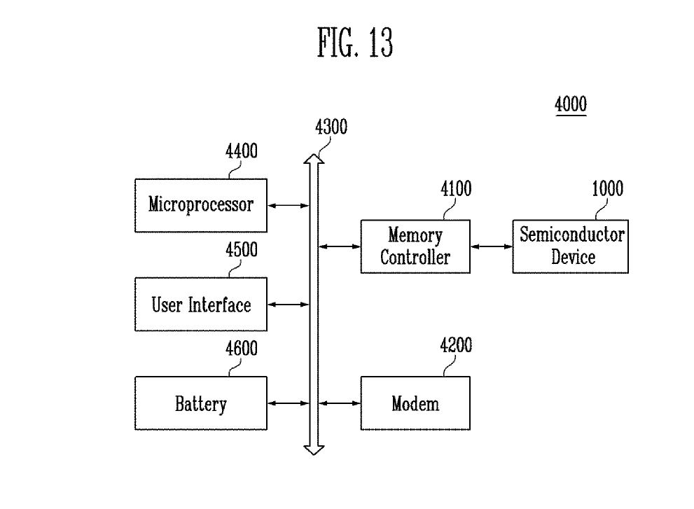

FIG. 12 is a block diagram illustrating a representation of an example of a memory system including a semiconductor device according to an embodiment.

Referring to FIG. 12, a memory system 3000 according to an embodiment may include a memory control unit 3100 and the semiconductor device 1000.

Since the semiconductor device 1000 may have substantially the same configuration as illustrated in FIG. 1, a detailed description thereof may be omitted.

The memory control unit 3100 may be configured to control the semiconductor device 1000. An SRAM 3110 may be used as a working memory of a CPU 3120. A host interface (I/F) 3130 may include a data exchange protocol of a host electrically coupled with the memory system 3000. An error correction circuit (ECC) 3140 in the memory control unit 3100 may detect and correct an error in data read from the semiconductor device 1000. A semiconductor I/F 3150 may interface with the semiconductor device 1000. The CPU 3120 may perform a control operation for data exchange of the memory control unit 3100. In addition, although not illustrated in FIG. 10, a ROM (not shown) for storing code data for interfacing with a host may be provided in the memory system 3000.

In an embodiment, the memory system 3000 may be applied to one of a computer, an Ultra Mobile PC (UMPC), a workstation, a net-book, a PDA, a portable computer, a web tablet, a wireless phone, a mobile phone, a smartphone, a digital camera, a digital audio recorder, a digital audio player, a digital picture recorder, a digital picture player, a digital video recorder, a digital video player, a device of transmitting and receiving information in a wireless environment, and various devices constituting a home network.

FIG. 13 is a block diagram illustrating a representation of an example of a computing system 400 including a semiconductor device according to an embodiment.

Referring to FIG. 13, the computing system 4000 includes an embodiment of a semiconductor device 1000 electrically coupled to a bus 4300, a memory controller 4100, a modem 4200, a microprocessor 4400, and a user interface 4500. When the computing system 4000 is a mobile device, a battery 4600 for supplying an operation voltage of the computing system 4000 may be additionally provided. The computing system 4000 may include an application chip set (not shown), a camera image processor (CIS) (not shown), a mobile DRAM (not shown), and the like.

The semiconductor device 1000 may be configured in substantially the same manner as the semiconductor device 1000 illustrated in FIG. 1. Thus, a detailed description thereof will be omitted.

The memory controller 4100 and the semiconductor device 1000 may be components of a Solid State Drive/Disk (SSD).

The semiconductor device 1000 and the memory controller 4100 may be mounted using various types of packages. For example, the semiconductor device 1000 and the memory controller 4100 may be mounted using packages such as Package on Package (PoP), Ball Grid Arrays (BGAs), Chip Scale Packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flat Pack (TQFP), Small Outline (SOIC), Shrink Small Outline Package (SSOP), Thin Small Outline (TSOP), System In Package (SIP), Multi Chip Package (MCP), Wafer-level Fabricated Package (WFP), Wafer-level Processed Stack Package (WSP), and the like.

According to the various embodiments, reliabilities of an erase operation and a read operation of a three-dimensional non-volatile memory device may be improved.

The various embodiments may provide a new operating methods and circuits for implementing the same in line with a changed structure of a memory array to increase the degree of integration, thereby increasing operating characteristics and reliability.

What is claimed is:

1. An operating method of a non-volatile memory device, the operating method comprising:
erasing memory cells included in a plurality of strings of a memory block, wherein the memory cells are coupled between a bit line and a common source line;
performing an erase verify operation on selected memory cells having a low erase speed, among the memory cells; and
repeating the erasing of the memory cells and the performing of the erase verify operation until the erase verify operation passes.

2. The operating method of claim 1, wherein the erasing of the memory cells is performed by using an incremental step pulse erase (ISPE) method.

3. The operating method of claim 1, wherein the erasing of the memory cells is performed by applying an erase voltage to the bit lines and the common source line and coupling word lines coupled to the memory cells to a ground terminal.

4. The operating method of claim 1, wherein the erase verify operation is performed by applying an erase verify voltage to word lines coupled to the selected memory cells and applying a pass voltage to remaining word lines.

5. The operating method of claim 4, wherein the erase verify operation passes when threshold voltages of the selected memory cells are lower than the erase verify voltage, and fails when at least one memory cell having a threshold voltage which is not lower than the erase verify voltage is detected among the memory cells.

6. The operating method of claim 5, wherein when the erase verify operation fails, the above steps are repeated until the erase verify operation passes.

7. The operating method of claim 1, further comprising performing a test operation to determine the selected memory cells having a slow erase speed, among the memory cells, before the erasing of the memory cells.

8. The operating method of claim 7, wherein the test operation comprises a test program operation, a test erase operation, and an address storing operation for the slow cells.

9. The operating method of claim 8, wherein the test program operation is performed by programming the memory block with arbitrary test data.

10. The operating method of claim 9, where the test program operation may be performed by an incremental step pulse program (ISPP) method or without performing a program verify operation.

11. The operating method of claim 8, wherein the test erase operation is performed by applying a test erase voltage to a bit line, a common source line and a pipe line coupled to the memory block.

12. The operating method of claim 11, wherein the test erase voltage has a shape of a single pulse or a plurality of erase pulses having a predetermined level.

13. The operating method of claim 8, wherein the address storing operation for the slow cells comprises:
performing a test erase verify operation to select the slow cells; and
storing address information about a page including the slow cells selected during the test erase verify operation.

14. The operating method of claim 13, wherein the test erase verify operation is performed by applying a test verify voltage to word lines coupled to the memory block.

15. The operating method of claim 14, wherein memory cells having higher threshold voltages than the test verify voltage are selected as the slow cells.

16. A non-volatile memory device, comprising:
a memory block configured for storing data;
a circuit group configured for performing a test operation and a main erase operation on the memory block;
a storage unit configured for storing address information about a page including slow cells; and
a control circuit configured for controlling the circuit group to erase memory cells included in the memory block during the main erase operation, perform an erase verify operation on the slow cells on the basis of the address information, and perform the main erase operation until the erase verify operation passes.

17. The non-volatile memory device of claim 16, wherein the control circuit controls the circuit group during the test operation to perform a test program operation to store arbitrary data in the memory block, perform a test erase operation to erase the memory block storing the arbitrary data, and perform a test erase verify operation to select the slow cells, among the memory cells included in the memory block.

18. The non-volatile memory device of claim 17, wherein the control circuit controls the circuit group so that the address information about the page including the slow cells selected during the test erase verify operation is stored in the storage unit.

19. The non-volatile memory device of claim 16, wherein the control circuit controls the circuit group so that the erase verify operation is not performed on remaining memory cells, except for the slow cells, while performing the main erase operation.

20. The non-volatile memory device of claim 16, wherein the control circuit controls the circuit group so that the main erase operation of the memory block is terminated when the erase verify operation on the slow cells passes.
